(19) United States
(12) Patent Application Publication
(10) Pub. No.: US 2012/0270389 A1
(43) Pub. Date: Oct. 25, 2012

(54) METHOD FOR MANUFACTURING INTERCONNECTION STRUCTURE AND OF METAL NITRIDE LAYER THEREOF

(75) Inventors: Chun-Ling LIN, Tainan County (TW); Chin-Fu Lin, Tainan City (TW); Chi-Mao Hsu, Tainan County (TW)

(73) Assignee: UNITED MICROELECTRONICS CORP., HSINCHU (TW)

(21) Appl. No.: 13/090,312

(22) Filed: Apr. 20, 2011

(51) Int. Cl. H01L 21/768; H01L 21/28

(52) U.S. Cl. 438/627; 438/685; 257/E21.158; 257/E21.584

(57) ABSTRACT

A method for manufacturing a metal nitride layer including the following steps is provided. Firstly, a substrate is provided. Then, a physical vapor deposition process is performed at a temperature between 210° C. and 390° C. to form a metal nitride layer on the substrate. Also, the physical vapor deposition process can be performed on a pressure between 21 mTorr and 91 mTorr. The method can be used in the manufacturing process of an interconnection structure for decreasing the film stress of the metal nitride layer. Therefore, the interconnection structure can be prevented from line distortion and film collapse.

### FIELD OF THE INVENTION

The present invention relates to a semiconductor process, and more particularly to methods for manufacturing an interconnection structure and for manufacturing a metal nitride layer thereof.

### DESCRIPTION OF THE RELATED ART

Since copper has a relatively low resistance value (30% less than aluminum) and a relatively good electro-migration resistance, and the low-k material, the porous low-k material and the ultra low-k material can make for reducing RC delay between metal wires, copper dual damascene technique with abovementioned low-k material is the best solution of metal interconnection for fabricating logic integrated circuit chips with high integration.

Generally, a metal hard mask (so-called MHM) is formed on the low-k dielectric layer to protect it from damage due to a chemical mechanical polishing (so-called CMP) process in the process of manufacturing the dual damascene interconnection structure. The metal hard mask is usually made by titanium nitride. However, the film stress of the metal hard mask or of other films would be increased in the manufacturing process of the metal hard mask. Therefore, the conductive line formed in the interconnection structure may be distorted. Further, the films may collapse resulted from the serious line distortion problem.

### BRIEF SUMMARY

The present invention relates to a method for manufacturing a metal nitride layer, which can decrease the film stress of the metal nitride layer.

The present invention relates to a method for manufacturing an interconnection structure, which can decrease the film stress of the interconnection structure and prevent the interconnection structure from line distortion and film collapse.

The present invention provides a method for manufacturing a metal nitride layer, which includes the following steps. Firstly, a substrate is provided. Then, a physical vapor deposition (so-called PVD) process is performed at a temperature between 210° C. and 390° C. to form a metal nitride layer on the substrate.

In an embodiment of the present invention, the physical vapor deposition process is performed on a pressure between 21 mTorr and 91 mTorr.

In an embodiment of the present invention, gases used in the physical vapor deposition process comprising argon and nitrogen.

In an embodiment of the present invention, the material of a target used in the physical vapor deposition process comprising titanium.

The present invention also provides a method for manufacturing a metal nitride layer, which includes the following steps. Firstly, a substrate is provided. Then, a physical vapor deposition process is performed on a pressure between 21 mTorr and 91 mTorr to form a metal nitride layer on the substrate.

In an embodiment of the present invention, gases used in the physical vapor deposition process comprising argon and nitrogen.

In an embodiment of the present invention, the material of a target used in the physical vapor deposition process comprising titanium.

The present invention further provides a method for manufacturing an interconnection structure, which includes the following steps. Firstly, a substrate having a first dielectric layer formed thereon and a first conductive wire layer embedded within the dielectric layer are provided. Secondly, a second dielectric layer is formed on the substrate. Next, a physical vapor deposition process is performed at a temperature between 210° C. and 390° C. to form a metal nitride layer on the second dielectric layer. After that, a portion of the metal nitride layer above the first conductive wire layer are removed, so as to form a first opening. Then, a photoresist layer with a second opening is formed on the metal nitride layer. The second opening is located corresponding to the first opening, and the diameter of the second opening is smaller than that of the first opening. Next, a portion of the second dielectric layer is removed by using the photoresist layer as a mask to form a via. Next, the photoresist layer is removed and a portion of the second dielectric layer is removed by using the metal nitride as a mask to form a trench to constitute a dual damascene opening with the via.

In an embodiment of the present invention, the physical vapor deposition process is performed on a pressure between 21 mTorr and 91 mTorr.

In an embodiment of the present invention, a barrier layer is formed on the substrate before forming the second dielectric layer.

In an embodiment of the present invention, a portion of the barrier layer is exposed by removing the portion of the second dielectric layer through using the photoresist layer as the mask. Further, the exposed portion of the barrier layer is also removed while removing the portion of the second dielectric layer by using the metal nitride layer as the mask.

In an embodiment of the present invention, a cap layer is formed on the second dielectric layer before forming the metal nitride layer.

In an embodiment of the present invention, a portion of the first conductive wire layer is exposed by the dual damascene opening.

In an embodiment of the present invention, a second conductive wire layer is formed and filled into the dual damascene opening for electrically connecting to the first conductive layer.

In an embodiment of the present invention, gases used in the physical vapor deposition process comprising argon and nitrogen.

In an embodiment of the present invention, the material of a target used in the physical vapor deposition process comprising titanium.

In an embodiment of the present invention, the method for forming the second conductive wire layer includes the steps of forming a metal layer on the metal nitride layer and filling into the dual damascene opening and removing the portion of the metal layer located on the metal nitride layer.

In an embodiment of the present invention, the metal nitride layer can be removed during the process of removing the portion of the metal layer located on the metal nitride layer.

In an embodiment of the present invention, the second dielectric layer can be made of low-k dielectric materials.

In the present invention, the metal nitride layer is formed by the physical vapor deposition process performed at a temperature between 210° C. and 390° C., and/or on a pressure between 21 mTorr and 91 mTorr. Therefore, the film stress of the metal nitride layer or of the other film of the interconnection structure can be decreased, so as to prevent the conductive wire layer of the interconnection structure from distorting and further prevent the interconnection structure from film collapse.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a flow chart of a method for manufacturing a metal nitride layer according to an embodiment of the present invention.

FIGS. 2A to 2H are cross-sectional, schematic views of an interconnection structure at stages in a manufacture process according to an embodiment of the present invention, where a trench is formed firstly.

### DETAILED DESCRIPTION

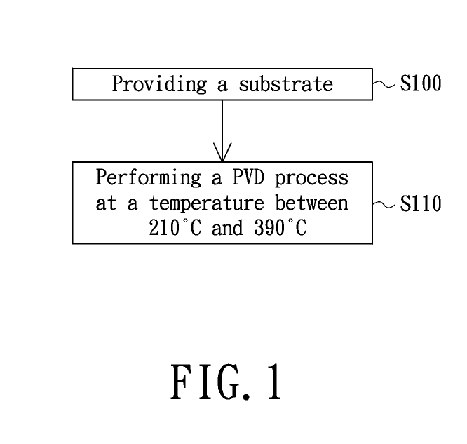

FIG. 1 is a flow chart of a method for manufacturing a metal nitride layer according to an embodiment of the present invention. Referring to FIG. 1, in the step S100, a substrate is provided. Next, in the step S110, a physical vapor deposition process is performed at a temperature between 210° C. and 390° C. to form a metal nitride layer on the substrate. In this embodiment, the physical vapor deposition process is, for example, a reactive sputtering process. Specifically, a target which used in the reactive sputtering process is made of titanium and the gases which used in the process include inert gas (e.g., argon) and nitrogen. The titanium atom fallen from the target due to be hit by the inert gas are reactive to each other, so as to deposit a titanium nitride layer on the substrate.

In the prior art skill, the metal nitride layer is deposited through a deposition process at room temperature (about 25° C.), so as to has a film stress about 2.5 GPa. In this embodiment, since the metal nitride layer is formed on the substrate by a physical vapor deposition process at a temperature higher than 300° C., the film stress of the metal nitride layer can be decreased to about 0.8 GPa.

Furthermore, in another embodiment of the present invention, the physical vapor deposition process also can be performed on a pressure between 21 mTorr and 91 mTorr. For example, the pressure is enhanced by increasing the flow of the gases, such as nitrogen and argon, used in the process. According to the experiment data, the metal nitride layer with a film stress about 0.3 GPa is deposited on the substrate by the physical vapor deposition process performed at 300° C. and 70 mTorr.

To better understand the present invention, the following will take a manufacture process of the interconnection structure with drawings as an example to explain the present invention, and the present invention is not limited hereto.

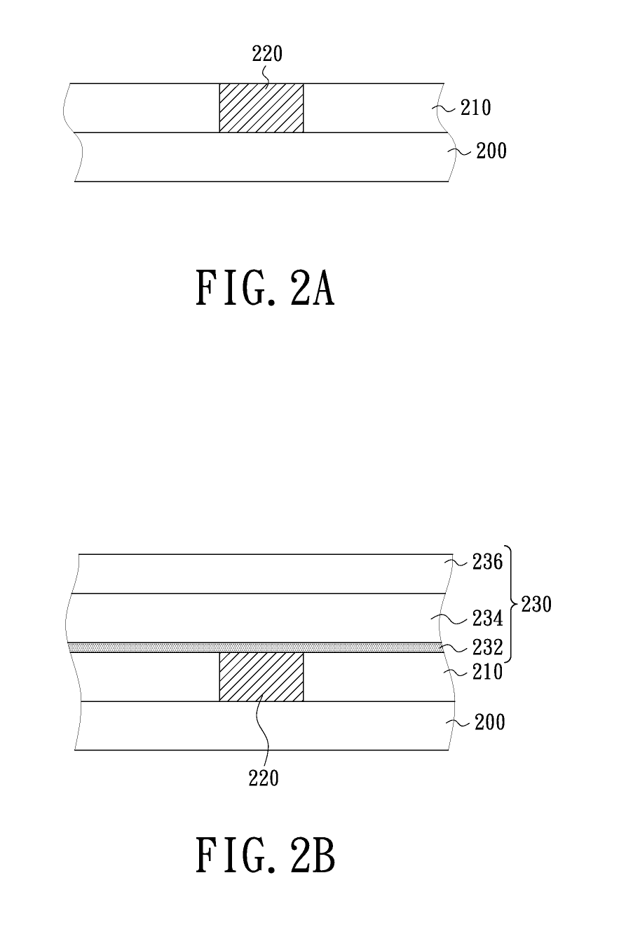

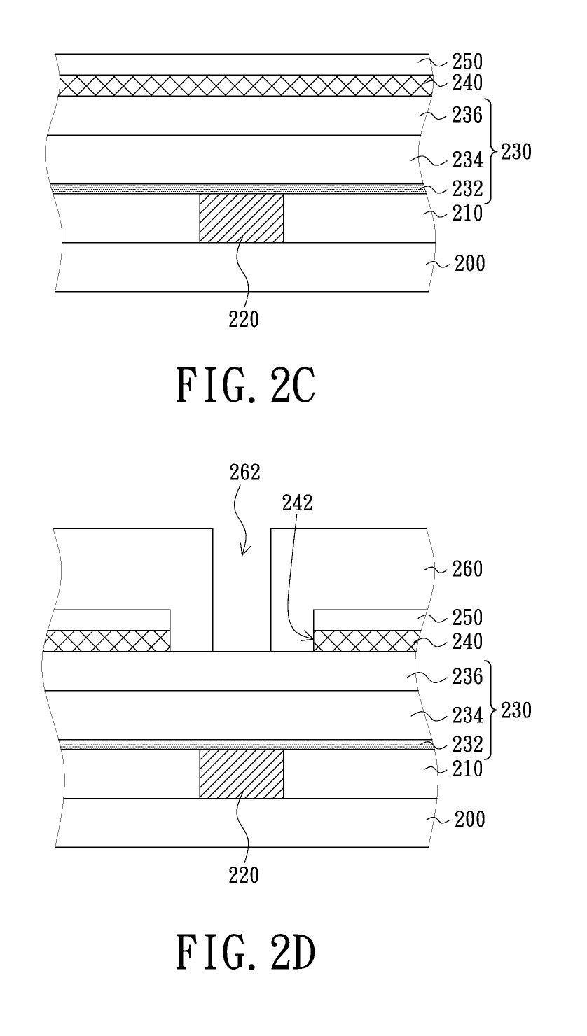

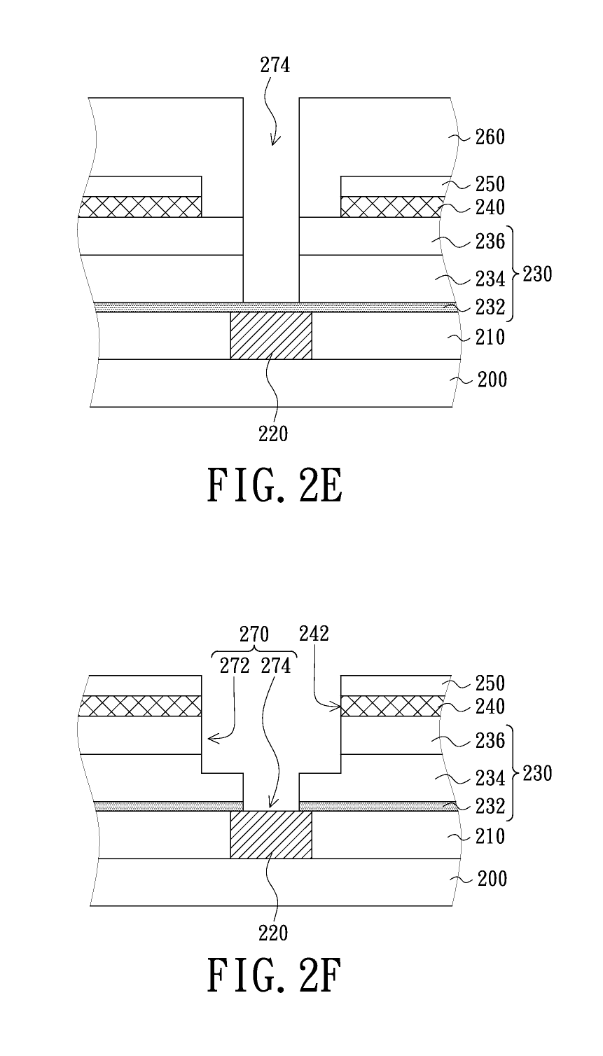

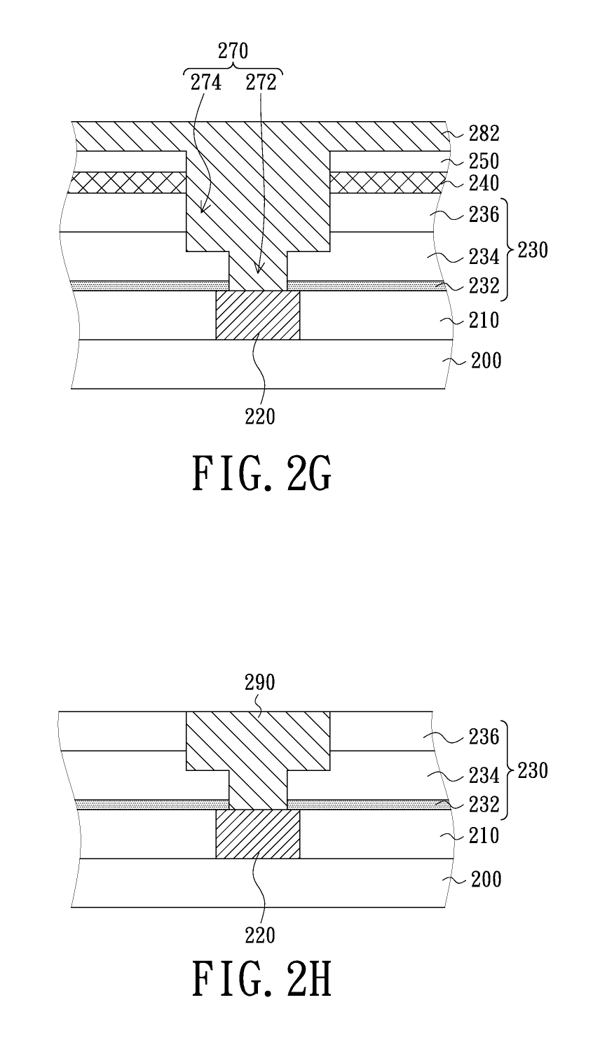

FIGS. 2A to 2H are cross-sectional, schematic views of an interconnection structure at stages in a manufacture process according to an embodiment of the present invention, where a trench is formed firstly. Referring to FIG. 2A, a substrate 200 is provided. The substrate 200 has a first dielectric layer 210 and a first conductive wire layer 220. The first conductive wire layer 220 can be embedded in the first dielectric layer 210. In the embodiment, material of the first conductive wire layer 220 is, for example, copper. Next, referring to FIG. 2B, a second dielectric layer 234 is formed on the substrate 200. In detail, a stacked structure 230 including a barrier layer 232, a second dielectric layer 234 and a cap layer 236 stacked in sequence is formed on the substrate. It should be noted that the barrier layer 232 and the cap layer 236 are optional to form on the substrate 200.

The barrier layer 232 is, for example, made of nitridation or oxidation, the second dielectric layer 234 is, for example, made of low-k dielectric materials and the cap layer 236 is, for example, made of tetraethoxysilane (TEOS) for protecting the second dielectric layer 234 from damages resulted from water. Moreover, the cap layer 236 may be made of multi-layers with different materials (e.g. SiON or TEOS), but the invention is not limited hereto.

Referring to FIG. 2C, a physical vapor deposition process is formed at a temperature between 210° C. and 390° C., so as to form a metal nitride layer 240 on the stacked structure 230 as a metal hard mask. In this embodiment, the metal nitride layer 240 is formed by reactive sputtering process and the material of the metal nitride layer 240 may be titanium nitride (TiN). That is, a target which used in the reactive sputtering process is made of titanium and the gases which used in the process include inert gas (e.g., argon) and nitrogen. The titanium atom fallen from the target due to be hit by the inert gas are reactive to each other, so as to deposit a titanium nitride layer (metal nitride layer 240) on the stacked structure 230.

As aforementioned, the film stress of the metal nitride layer 240 can be decreased to 0.3 GPa through depositing the metal nitride layer 240 by a physical vapor deposition process at the temperature higher than 210° C. Furthermore, the physical vapor deposition process also can be performed on a pressure between 21 mTorr and 91 mTorr in this embodiment, so as to further decrease the film stress of the metal nitride layer 240 to 0.3 GPa.

Moreover, an anti-reflective dielectric layer 250 is optional formed on the metal nitride layer 240. In this embodiment, the anti-reflective dielectric layer 250 is made of silicon oxynitride.

Referring to FIG. 2D, a portion of the metal nitride layer 240 and a portion of the anti-reflective dielectric layer 250 above the first conductive wire layer 220 to form a first opening 242. Then, a photoresist layer 260 with a second opening 262 is formed on the anti-reflective dielectric layer 250. The second opening 262 corresponds to the first opening 242 and the diameter of the second opening 262 is smaller than that of the first opening 242.

Referring to FIG. 2E, a portion of the cap layer 236 and a portion of the second dielectric layer 234 exposed by the second opening 262 are removed by using the photoresist layer 260 as the mask, therefore a via 274 exposing the portion of the barrier layer 232 above the first conductive wire layer 220 is formed.

Referring to FIG. 2F, the photoresist layer 260 is removed and a portion of the cap layer 236, and a portion of the second dielectric layer 234 exposed by the first opening 242 are removed by using the metal nitride layer 240 and the anti-reflective dielectric layer 250 as the mask to form a trench 272. At the same time, the exposed portion of the bather layer 232 is also removed to form a via 274 exposing a portion of the first conductive wire layer 220. Therefore, a dual damascene opening 270 is constituted of the trench 272 and the via 274.

Referring to FIG. 2G, a metal layer 282 is formed on the anti-reflective dielectric layer 250 and filled into the dual damascene opening 270 to electrically connect with the first conductive wire layer 220. Then, as shown in FIG. 2H, the portion of the metal 282 located on the anti-reflective dielectric layer 250 is removed, therefore a second conductive wire layer 290 filled in the dual damascene opening 270 is formed, so as to form the interconnection structure of this embodiment. Specifically, the portion of the metal 282 located on the anti-reflective dielectric layer 250 is removed, for example, by performing a chemical mechanical polishing (CMP) process. Furthermore, the anti-reflective dielectric layer 250 and the metal nitride layer 240 may also be removed during the CMP process.

In summary, the metal nitride layer of one embodiment of the present invention is formed by a physical vapor deposition process at a temperature higher than 210° C., so as to decrease the film stress of the metal nitride layer. Moreover, the physical vapor deposition process also can performed on a pressure higher then 21 mTorr for further decrease the film stress of the metal nitride layer. Therefore, the interconnection structure can be prevented from line distortion and film collapse.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A method for manufacturing a metal nitride layer, comprising the following steps:
providing a substrate; and
performing a physical vapor deposition process at a temperature between 210° C. and 390° C. to form a metal nitride layer on the substrate.

2. The method for manufacturing a metal nitride layer as claimed in claim 1, wherein the physical vapor deposition process is performed on a pressure between 21 mTorr and 91 mTorr.

3. The method for manufacturing a metal nitride layer as claimed in claim 1, wherein the physical vapor deposition process comprises reactive sputtering.

4. The method for manufacturing a metal nitride layer as claimed in claim 1, wherein gases used in the physical vapor deposition process comprising argon and nitrogen.

5. The method for manufacturing a metal nitride layer as claimed in claim 1, wherein the material of a target used in the physical vapor deposition process comprising titanium.

6. A method for manufacturing a metal nitride layer, comprising the steps:
providing a substrate; and
performing a physical vapor deposition process on a pressure between 21 mTorr and 91 mTorr to form a metal nitride layer on the substrate.

7. The method for manufacturing a metal nitride layer as claimed in claim 6, wherein the physical vapor deposition process comprises reactive sputtering.

8. The method for manufacturing a metal nitride layer as claimed in claim 6, wherein gases used in the physical vapor deposition process comprising argon and nitrogen.

9. The method for manufacturing a metal nitride layer as claimed in claim 6, wherein the material of a target used in the physical vapor deposition process comprising titanium.

10. A method for manufacturing an interconnection structure, comprising the following steps:
providing a substrate having a first dielectric layer and a first conductive wire layer formed thereon, wherein the first conductive wire layer embedded within first the dielectric layer;
forming a second dielectric layer on the substrate;
performing a physical vapor deposition process at a temperature between 210° C. and 390° C. to form a metal nitride layer on the stacked structure;
removing a portion of the metal nitride layer above the first conductive wire layer to form a first opening;
forming a photoresist layer with a second opening corresponding to the first opening, wherein the diameter of the second opening being smaller than that of the first opening;
removing a portion of the second dielectric layer by using the photoresist layer as mask to form a via;
removing the photoresist layer; and
removing a portion of the second dielectric layer by using the metal nitride layer to form a trench to constitute a dual damascene opening with the via.

11. The method for manufacturing an interconnection structure as claimed in claim 10, wherein the wherein the physical vapor deposition process is performed on a pressure between 21 mTorr and 91 mTorr.

12. The method for manufacturing an interconnection structure as claimed in claim 10, further comprises a step of forming a barrier layer on the substrate before forming the second dielectric layer.

13. The method for manufacturing an interconnection structure as claimed in claim 12, wherein a portion of the barrier layer is exposed after the portion of the second dielectric layer is removed by using the photoresist layer as mask, and the method further comprises a step of removing the exposed portion of the barrier layer while the second dielectric layer removed by using the metal nitride layer as mask.

14. The method for manufacturing an interconnection structure as claimed in claim 12, further comprises a step of forming a cap layer on the second dielectric layer before forming the metal nitride layer.

15. The method for manufacturing an interconnection structure as claimed in claim 10, wherein a portion of the first conductive wire layer is exposed by the dual damascene opening.

16. The method for manufacturing an interconnection structure as claimed in claim 15, further comprises a step of forming a second conductive wire layer filled in the dual damascene opening and electrically connected to the first conductive wire layer.

17. The method for manufacturing an interconnection structure as claimed in claim 16, wherein the method for forming the second conductive wire layer comprises the steps of:
forming a metal layer on the metal nitride layer, wherein the metal layer filled into the dual damascene opening; and
removing a portion of the metal layer located on the metal nitride layer.

18. The method for manufacturing an interconnection structure as claimed in claim 17, further comprising the step of removing the metal nitride layer while removing the portion of the metal layer located on the metal nitride layer.

19. The method for manufacturing an interconnection structure as claimed in claim 10, wherein the physical vapor deposition process comprises reactive sputtering.

20. The method for manufacturing an interconnection structure as claimed in claim 10, wherein gases used in the physical vapor deposition process comprising argon and nitrogen.

21. The method for manufacturing an interconnection structure as claimed in claim 10, wherein the material of a target used in the physical vapor deposition process comprises titanium.

22. The method for manufacturing an interconnection structure as claimed in claim 10, wherein the material of the second dielectric layer comprises low-k dielectric materials.
